(19) United States
(12) Patent Application Publication
(10) Pub. No.: US 2019/0390949 A1
(43) Pub. Date: Dec. 26, 2019

(54) METHODS, APPARATUSES AND SYSTEMS FOR CONDUCTIVE FILM LAYER THICKNESS MEASUREMENTS

(71) Applicant: APPLIED MATERIALS, INC., Santa Clara, CA (US)

(72) Inventors: KAI WU, Palo Alto, CA (US); WEI MIN CHAN, Sunnyvale, CA (US); PEIQI WANG, San Jose, CA (US); PAUL MA, Santa Clara, CA (US); EDWARD BUDIARTO, Fremont, CA (US); KUN XU, Sunol, CA (US); TODD J. EGAN, Fremont, CA (US)

(21) Appl. No.: 16/432,104

(22) Filed: Jun. 5, 2019

Related U.S. Application Data
(60) Provisional application No. 62/687,995, filed on Jun. 21, 2018.

(51) Int. Cl. G01B 7/06; C23C 16/52

(52) U.S. Cl. CPC G01B 7/105; G01R 27/14; C23C 16/52

(57) ABSTRACT

A method and system for determining a thickness of a conductive film layer deposited on a wafer include at two eddy current sensors to take electrical resistivity measurements of the conductive film layer on the wafer as the wafer is being transported by a robot arm, a temperature sensor to determine a temperature change of the wafer during the electrical resistivity measurement, and a processing device to adjust a value of the electrical resistivity measurement by an amount based on the determined temperature change and to determine a thickness of the conductive film layer using the adjusted value of the electrical resistivity measurement and a previously determined correlation between electrical resistivity measurement values and respective thicknesses of conductive film layers. Alternatively, the wafer can be kept at a steady temperature when taking electrical resistivity measurements of the conductive film layer to determine a thickness of the conductive film layer.

### CROSS-REFERENCE TO RELATED APPLICATIONS

This application claims priority to and the benefit of U.S. Provisional Patent Application Ser. No. 62/687,995, filed Jun. 21, 2018, which is incorporated herein by this reference in its entirety.

### FIELD

Embodiments of the present principles relate generally to layer thickness measurement, and, more particularly, to conductive film layer thickness measurement using contactless, resistivity measurements.

### BACKGROUND

Integrated circuits are generally manufactured by forming various materials, such as metals and dielectrics, on a wafer to create composite thin films and patterning the layers. It can often be useful to have an accurate measure of the thickness of a layer formed on a substrate. For example, a layer can be initially over-deposited onto the wafer to form a relatively thick layer. Knowing the thickness of the layer can help control the deposition process to more accurately deposit a layer onto the wafer.

### SUMMARY

Methods, apparatuses and systems for determining a thickness of a conductive film layer deposited on a wafer are provided herein.

In some embodiments, a method for determining a thickness of a conductive film layer deposited on a wafer includes taking a contactless, electrical resistivity measurement of the conductive film layer on the wafer as the wafer is being transported by a robot arm, determining a temperature change of the wafer during the electrical resistivity measurement, adjusting a value of the electrical resistivity measurement by an amount based on the determined temperature change, and determining a thickness of the conductive film layer using the adjusted value of the electrical resistivity measurement and a previously determined correlation between electrical resistivity measurement values and respective thicknesses of conductive film layers.

In some embodiments, an amount to adjust a value of the electrical resistivity measurement is determined using a first calibration process, which includes taking a contactless, electrical resistivity measurement of the conductive film layer during a plurality of temperature change ranges, and comparing a value of the electrical resistivity measurement for each of the plurality of temperature change ranges with a previously determined value of an electrical resistivity measurement of the conductive film layer taken during a constant, reference temperature to determine an effect of each of the temperature change ranges on an electrical resistivity measurement. In some embodiments, the amount by which to adjust the value of the electrical resistivity measurement is proportional to the effect the temperature change has on an electrical resistivity measurement.

In some embodiments, the correlation between electrical resistivity measurement values and respective thicknesses of conductive film layers is determined using a second calibration process, which includes taking contactless, electrical resistivity measurements of a plurality of conductive film layers, taking thickness measurements of the plurality of conductive film layers using a thin-film metrology, and correlating the contactless, electrical resistivity measurements of the plurality of conductive film layers with respective thin-film, metrology thickness measurements of the plurality of conductive film layers.

In alternate embodiments, the second calibration process includes taking contactless, electrical resistivity measurements of a plurality of conductive film layers having known thicknesses, and correlating the contactless, electrical resistivity measurements of the plurality of conductive film layers with respective thicknesses of the plurality of conductive film layers.

In some embodiments, a method for determining a thickness of a conductive film layer deposited on a wafer includes maintaining the wafer at a constant temperature during an electrical resistivity measurement, taking a contactless, electrical resistivity measurement of the conductive film layer on the wafer as the wafer is being transported by a robot arm, determining a temperature of the wafer during the electrical resistivity measurement, and determining a thickness of the conductive film layer using a value of the electrical resistivity measurement and a previously determined correlation between electrical resistivity measurement values and respective thicknesses of conductive film layers.

In some embodiments, the correlation between electrical resistivity measurement values and respective thicknesses of conductive film layers is determined using a calibration process, which includes taking contactless, electrical resistivity measurements of a plurality of conductive film layers, taking thickness measurements of the plurality of conductive film layers using a thin-film metrology, and correlating the contactless, electrical resistivity measurements of the plurality of conductive film layers with respective thin-film, metrology thickness measurements of the plurality of conductive film layers. In alternate embodiments, the calibration process includes taking contactless, electrical resistivity measurements of a plurality of conductive film layers having known thicknesses, and correlating the contactless, electrical resistivity measurements of the plurality of conductive film layers with respective thicknesses of the plurality of conductive film layers.

In some embodiments, a system for determining a thickness of a conductive film layer deposited on a wafer includes at least two eddy current sensors to capture, electrical resistivity measurements of the conductive film layer, wherein a first of the at least two eddy current sensors is configured to capture electrical resistivity measurements from above the wafer and wherein a second of the at least two eddy current sensors is configured to capture electrical resistivity measurements from below the wafer, a temperature sensor to sense at least a temperature of the wafer, and a processing device including a memory for storing program instructions, tables and data, and a processor for executing the program instructions. When executed by the processor, the program instructions cause the system to capture a contactless, electrical resistivity measurement of the conductive film layer on the wafer as the wafer is being transported by a robot arm across the at least two eddy current sensors, determine a temperature change of the wafer during the electrical resistivity measurement using the temperature sensor, adjust a value of the electrical resistivity measurement by an amount based on the determined temperature change and determine a thickness of the conductive film layer using the adjusted value of the electrical resistivity measurement and a previously determined correlation between electrical resistivity measurement values and respective thicknesses of conductive film layers. In some embodiments, the previously determined correlation between electrical resistivity measurement values and respective thicknesses of conductive film layers is stored as a table in the memory of the processing device.

In alternate embodiments, a system for determining a thickness of a conductive film layer deposited on a wafer includes at least two eddy current sensors to take electrical resistivity measurements of the conductive film layer, wherein a first of the at least two eddy current sensors is configured to capture electrical resistivity measurements from above the wafer and wherein a second of the at least two eddy current sensors is configured to capture electrical resistivity measurements from below the wafer, a temperature controller to control at least a temperature of the wafer, a temperature sensor to sense at least a temperature of the wafer, and a processing device including a memory for storing program instructions, tables and data, and a processor for executing the program instructions. When executed by the processor, the program instructions cause the system to maintain the wafer at a constant temperature during an electrical resistivity measurement using the temperature controller, capture a contactless, electrical resistivity measurement of the conductive film layer on the wafer as the wafer is being transported by a robot arm across the at least two eddy current sensors, determine a temperature of the wafer during the electrical resistivity measurement using the temperature sensor, and determine a thickness of the conductive film layer using a value of the electrical resistivity measurement and a previously determined correlation between electrical resistivity measurement values and respective thicknesses of conductive film layers.

Other and further embodiments of the present principles are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate typical embodiments of the disclosure and are therefore not to be considered limiting of scope, for the disclosure may admit to other equally effective embodiments.

FIG. 1 depicts a high level block diagram of a chemical vapor deposition (CVD) process system including an embodiment of a conductive layer measurement system in accordance with an embodiment of the present principles.

FIG. 2 depicts a high level block diagram of an embodiment of an eddy current sensor suitable for use in the CVD process system of FIG. 1 in accordance with an embodiment of the present principles.

FIG. 3 depicts a flow diagram of a method for measuring a thickness of a layer deposited on a wafer in accordance with an embodiment of the present principles.

FIG. 4 depicts a high level block diagram of a processing device suitable for use in the CVD process system of FIG. 1 in accordance with an embodiment of the present principles.

FIG. 5 depicts a flow diagram of a method for measuring a thickness of a layer deposited on a wafer in accordance with another embodiment of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods, apparatuses and systems for layer thickness measurements, for example, of film layers deposited on wafers during a chemical vapor deposition process are provided herein.

In various embodiments in accordance with the present principles, a conductive layer measurement system for measuring a conductive layer deposited on a wafer includes at least two eddy current sensors located on either side of a robot blade of a CVD process system. A thickness of the deposited, conductive layer is measured as a wafer is moved between chambers of a CVD process system. In some embodiments in accordance with the present principles, the conductive layer measurement system includes a non-contact temperature compensation technique to mitigate the effect of temperature variability inherent in the measurement of a wafer cooling after a thermal process.

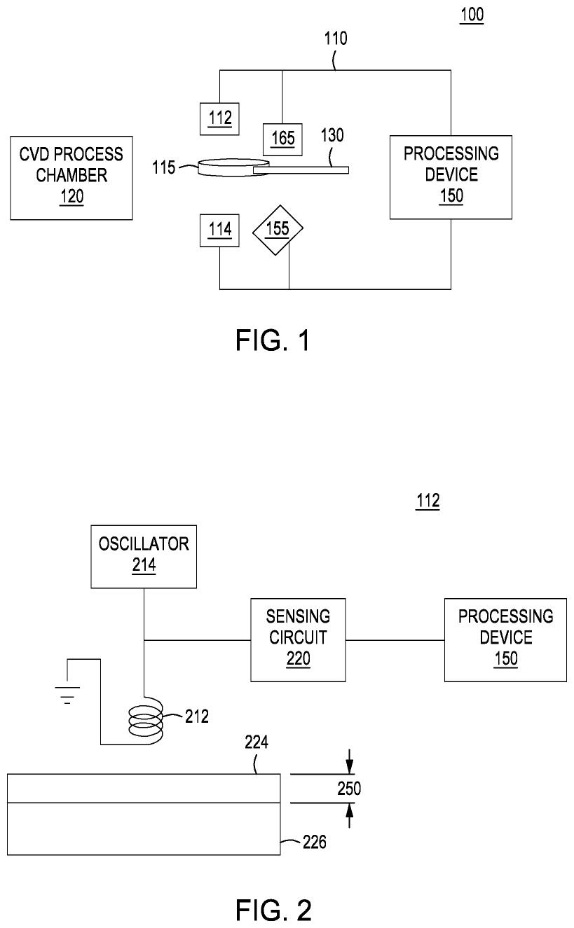

FIG. 1 depicts a high level block diagram of a chemical vapor deposition (CVD) process system 100 including an embodiment of a conductive layer measurement system 110 in accordance with an embodiment of the present principles. The conductive layer measurement system 110 of FIG. 1 illustratively comprises two eddy current sensors 112, 114 in communication with a processing device 150, a temperature sensor 155 and a temperature controller 165. In the CVD process system 100 FIG. 1, the conductive layer measurement system 110 is implemented to measure a conductive layer deposited on a wafer 115 in a CVD process chamber 120 of the CVD process system 100. That is, in the CVD process system 100 of FIG. 1, a conductive layer, such as tungsten, is deposited on the wafer 115 in the CVD chamber 120. Although in the embodiment of the conductive layer measurement system 110 depicted in FIG. 1, the conductive layer measurement system 110 illustratively comprises a temperature sensor 155 and a temperature controller 165, in other embodiments conductive layer measurement systems in accordance with the present principles do not include a temperature sensor 155 and a temperature controller 165.

A robot blade 130 of the CVD process system 100 removes the processed wafer 115 from the CVD process chamber 120 to be transferred to another location for further processing. During the transfer of the processed wafer 115 by the robot blade 130, the conductive layer measurement system 110 measures a thickness of the conductive film layer deposited on the wafer 115 by the CVD process chamber 120 by positioning one of the two eddy current sensors 112, 114 on either side of the robot blade 130 (i.e., one eddy current sensors on one side of the wafer and the other current eddy sensor on the other side of the wafer) and measuring a resistivity associated with the conductive film layer from both sides of the wafer as depicted in the embodiment of FIG. 1 and as will be described in further detail below.

In some embodiments, described in detail further below, the wafer 115 is maintained at a constant temperature by a temperature controller 165 during the electrical resistivity measurements by the eddy current sensors 112, 114 as the wafer 115 is being transported by a robot arm 130. As such, a thickness of the conductive film layer is determined using a value of an electrical resistivity measurement and a previously determined correlation between electrical resistivity measurement values and respective thicknesses of conductive film layers. In such embodiments, a temperature of the wafer 115 can be determined by a temperature sensor 155 during the electrical resistivity measurement to verify the temperature of the wafer 115.

In some embodiments, described in detail further below, a temperature change of the wafer 115 can be determined by the temperature sensor 155 during the electrical resistivity measurements by the eddy current sensors 112, 114 themselves as the wafer 115 is being transported by a robot arm 130. A value of the electrical resistivity measurement can then be adjusted by an amount based on the determined temperature change and a thickness of the conductive film layer can be determined using a value of the electrical resistivity measurement and a previously determined correlation between electrical resistivity measurement values and respective thicknesses of conductive film layers.

FIG. 2 depicts a high level block diagram of an embodiment of an eddy current sensor 112 suitable for use in the CVD process system 100 of FIG. 1 in accordance with an embodiment of the present principles. The eddy current sensor 112 of FIG. 2 illustratively includes a coil 212 and a signal oscillator 214 such as an alternating current (AC) signal source. In the embodiment of FIG. 2, the coil 212, driven by the oscillating signal source 214, generates an oscillating magnetic field which induces circular electrical currents inside a nearby conductive material of a conductive film layer 224 of a wafer 226 under test. The conductive film layer 224 deposited using a CVD processes can include an electrically conductive metal. The induced eddy currents in turn generate their own magnetic fields which oppose the magnetic field generated by the coil 212.

The interaction between the generated magnetic fields and the induced magnetic fields alters the complex impedance of the coil 212, which can be detected by a sensing circuit 220 connected to the coil 212. The output of the sensing circuit (not shown) can be communicated to, for example, the processing device 150 of FIG. 1 or other computational device to provide a useful measurement of the thickness of the conductive film layer 224 on the wafer 226 as described below.

For example, the degree to which the complex impedance of the coil 212 is altered can be considered as a function of the strength of the magnetic fields induced by the eddy currents. In turn, the strength of the induced eddy currents can be considered as a function of the electrical conductivity of the conductive material and the distance between the coil 212 and the conductive material of the conductive film layer 224. The size of the eddy current is proportional to the size of the magnetic field and inversely proportional to the resistivity of a conductive film layer being measured. When the thickness 250 of the conductive film layer 224 is less than the penetration depth of the external magnetic field at the driving frequency of the signal oscillator 214, the induced eddy current is a function of the thickness 250 of the conductive film layer 224.

In accordance with embodiments of the present principles, a calibration process(es) can be performed to correlate a resistivity measurement resulting from a measurement of a conductive film using eddy current sensors, as described above, with an absolute film thickness. For example, in accordance with some embodiments of the present principles, respective resistivity values are acquired for conductive film layers having known film thicknesses, such as tungsten, using the eddy current measurement process of the conductive layer measurement system 110 of FIG. 1 described above. The calibration process is used to map resistivity measurements determined via the eddy current measurement process of the conductive layer measurement system 110 with respective, known film thicknesses for conductive films. Such a calibration process can be performed for various conductive materials and conductive material combinations and for a plurality of thicknesses. The results can be arranged as a table/map correlating eddy current resistivity measurements acquired using the conductive layer measurement system 110 with respective, known thicknesses of conductive film layers. Such correlations (i.e., table) can be stored in a memory of, for example, the processing device 150.

Alternatively or in addition, in accordance with some embodiments of the present principles, a different calibration process(es) can be performed to correlate a resistivity measurement resulting from a measurement of a conductive film layer using eddy current sensors, as described above, with a thickness of a conductive film layer. In such embodiments, conductive films, such as “typical” tungsten films, can be measured using a thin film metrology. In such embodiments, the conductive films are also measured using the eddy current measurement process of the conductive layer measurement system 110 described above. The calibration process maps resistivity measurements determined via the eddy current measurement process of the conductive layer measurement system 110 described above with respective, thickness measurements of conductive film layers acquired using the implemented metrology for various thicknesses and various conductive film layer types.

In such embodiments, a calibration table can be created that correlates resistivity measurements of conductive films acquired by the conductive layer measurement system 110 to thickness measurements of the conductive films acquired using the implemented metrology. As such, subsequently when a resistivity measurement of a specific conductive film layer is acquired by a conductive layer measurement system in accordance with the present principles, such as the conductive layer measurement system 110 of FIG. 1, a correlation can be made by, for example, the processing device 150 between the resistivity measurement acquired by the conductive layer measurement system 110 and a respective thickness measurement acquired using the thin film metrology for that specific conductive film layer by referring to a created calibration table that can be stored in a memory of the processing device 150.

The thickness measurement acquired by an eddy current sensor can be a function of the distance 252 between the coil 212 of eddy current sensor 112 and the film 224. This distance 252 is frequently referred to as the “lift-off” distance. More specifically, a variable that can affect a resistivity measurement and ultimately a thickness measurement of a conductive film layer determined by eddy current sensors in accordance with embodiments of the present principles, is a distance between a coil of an eddy current sensor and a deposited conductive film layer being measured, and in particular, changes in the distance between a coil of an eddy current sensor and a conductive film layer deposited on a wafer. Therefore, a reliable film thickness measurement can depend upon a good measurement of the lift-off distance and the ability to keep the lift-off distance constant.

Referring back to the embodiment of FIG. 1, the conductive layer measurement system 110 of the chemical vapor deposition (CVD) process system 100 compensates for varying distances between an eddy current sensor(s) and a conductive film layer on a wafer that is being measured, inherent in a measurement performed on a moving robot blade in accordance with embodiments of the present principles, by positioning a first eddy current sensor 112 above the robot blade 130 and a second eddy current sensor 114 below the robot blade 130. More specifically, the readings from the first eddy current sensor 112 above the robot blade 130 and the second eddy current sensor 114 below the robot blade 130 are rectified to compensate for a wafer moving closer to one eddy current sensor, which incidentally means that the same wafer is moving away from the second eddy current sensor. That is, the readings from the first eddy current sensor 112 above the robot blade 130 and the second eddy current sensor 114 below the robot blade 130 are combined into a single reading that is a function of both readings. In some embodiments in accordance with the present principles, a sum of the readings from the first eddy current sensor 112 above the robot blade 130 and the second eddy current sensor 114 below the robot blade 130 are used to produce a constant distance reading.

Other variables that can affect a resistivity measurement acquired using eddy current sensors and ultimately a thickness determination for a conductive film layer made in accordance with embodiments of the present principles, include temperature differences between resistivity measurements and temperature changes during a resistivity measurement. With respect to the former, resistivity measurements acquired by the conductive layer measurement system 110 on a conductive film layer deposited on a wafer for a same conductive film layer will be different at different temperatures.

In some embodiments in accordance with the present principles, to compensate for the effect of differences in temperature on resistivity measurements acquired by the conductive layer measurement system 110, a wafer 115 having a conductive film layer being measured can be maintained at a specific temperature. In one embodiment in accordance with the present principles, the conductive layer measurement system 110 of FIG. 1 can include a temperature controller 165 in communication with processing device 150 for maintaining the wafer 115 at a specific temperature by heating or cooling the wafer 115 and a temperature sensor 155 in communication with processing device 150 for measuring temperatures. Although in FIG. 1 the temperature controller 165 is depicted as being a separate component not in contact with the wafer 115, in alternate embodiments, the temperature controller 165 can be an integrated component of another component of FIG. 1 and can be in contact with the wafer 115 or the robot arm 130 for controlling a temperature of the wafer 115 and, as such, controlling a temperature of the conductive film layer on the wafer 115 such that the conductive film layer maintains a steady temperature during a thickness measurement acquired by the conductive layer measurement system 110.

In some embodiments, to correlate resistivity measurements of a conductive film layer on the wafer with a known thickness of the conductive film layer for conductive film layers of different types and thicknesses at various temperatures, a calibration process(es) can be performed. For example, in some embodiments of a calibration process, resistivity measurements for a known conductive film layer having a known thickness can be acquired at incremental temperatures (e.g., 2 degrees) between measurements. The resistivity measurements acquired for the known conductive film layer having the known thickness for each temperature can be memorialized (e.g., stored). An effect on a resistivity measurement acquired for the known conductive film layer having the known thickness for a specific temperature can then be determined by referring to a difference between a resistivity measurement taken at a “reference” (e.g., typical) temperature for the known conductive film layer having the known thickness and a resistivity measurement for the known conductive film layer having the known thickness taken at a different temperature. In some embodiments, the “reference” (e.g., typical) temperature measurements can be obtained from previous calibration processes as described above.

Subsequently, when a resistivity measurement is acquired for a conductive film layer at a temperature for which a calibration measurement was not previously acquired, the acquired resistivity measurement can be adjusted by an amount equal to a determined effect of a temperature difference on the resistivity measurement to determine an adjusted resistivity measurement for the conductive film layer. An accurate thickness measurement for the conductive film layer can then be determined by referring to, for example, a table or map, correlating the adjusted resistivity measurement with a thickness measurement for the conductive film layer. In some embodiments in accordance with the present principles, such a determination can be made by, for example, the processing device 150. In such embodiments, a temperature of the wafer can be determined by the temperature sensor 155 to ensure that the wafer is being maintained at a constant temperature and to verify the temperature at which the wafer is being maintained.

In some embodiments in accordance with the present principles, to enable a compensation of the effect of different temperatures on resistivity measurements acquired by the conductive layer measurement system 110, a calibration process can be performed to enable a correlation between resistivity measurements acquired by the conductive layer measurement system 110 of conductive film layers at different temperatures to respective thicknesses of the conductive film layers. For example, in some embodiments in accordance with the present principles, a resistivity measurement of a particular conductive film layer having a known thickness is acquired by the conductive layer measurement system 110 at a number of different temperatures. A respective resistivity measurement acquired by the conductive layer measurement system 110 is mapped to the particular conductive film layer having a known thickness at a particular temperature for the number of different temperatures and for a plurality of different conductive film layer types having respective, known thicknesses.

As such, subsequently when a resistivity measurement of a specific conductive film layer type is acquired by the conductive layer measurement system 110 at a controlled temperature, a correlation can be made by, for example, the processing device 150 between the resistivity measurement acquired by the conductive layer measurement system 110 at that controlled temperature and a respective thickness measurement for that specific type of conductive film layer by referring to the mapping of the calibration process, which can take the form of a created calibration table that can be stored in a memory of, for example, the processing device 150. That is, a thickness can be determined for a specific type of conductive film layer by acquiring a resistivity measurement for the conductive film layer in accordance with the present principles, and referring to a mapping between a resulting resistivity measurement and a film thickness correlated with the measured resistivity for the conductive film layer of that specific type at the specific temperature. In such embodiments in accordance with present principles, a conductive layer measurement system 110 can include at least one of a temperature sensor 155 and a temperature controller 165 as described above.

Referring back to FIG. 1 and with reference to the latter effect of temperature changes on resistivity measurements, because film deposition occurs at an elevated temperature, film thickness measurements in accordance with embodiments of the present principles can occur during a time period when a wafer is cooling off, for example, when the wafer is being transferred between chambers, for example, by the robot blade 130 of FIG. 1. That is, in some instances when a wafer 115 is removed from the process chamber 120 by the robot arm 130, a resistivity of the conductive film layer on the wafer 115 can be measured by the conductive layer measurement system 110 as described above to determine a thickness of the conductive film layer. While the wafer 115 is moving across the conductive layer measurement system 110 and a resistivity measurement is being acquired of the conductive film layer on the wafer 115, the wafer 115 removed from the process chamber 120 can be cooling off. Changes in temperature during a resistivity measurement in accordance with the present principles can effect resistivity measurements acquired by the conductive layer measurement system 110 and ultimately effect a resulting thickness determination for a conductive film layer on the wafer 115.

In some embodiments in accordance with the present principles, to enable a compensation of the effect of temperature changes during the acquisition of resistivity measurements of conductive film layers by the conductive layer measurement system 110, a calibration process can be performed to quantify the effect of temperature changes on resistivity measurements acquired by the conductive film layer measurement system 110. For example, resistivity measurements can be acquired for a plurality of different known conductive film types having respective known thicknesses during various different temperature changes (e.g., different degrees of cooling of the wafer during respective resistivity measurements by the conductive layer measurement system 110). An effect on resistivity measurements due to temperature changes of the wafer during resistivity measurements by the conductive layer measurement system 110 can then be determined by comparing resulting resistivity measurements acquired during a temperature change with a respective resistivity measurement previously acquired for a same conductive film layer type having a same thickness during a steady temperature for a similar temperature value. Such effects can be determined for various temperature change ranges to determine the effect of various temperature change ranges on respective resistivity measurements acquired during the respective temperature change ranges.

Subsequently, when a resistivity measurement is acquired for a conductive film layer during a temperature change of a wafer on which the conductive film layer is deposited, the acquired resistivity measurement can be adjusted by an amount equal to a determined effect of the temperature change on the resistivity measurement to determine an adjusted resistivity measurement for the measured conductive film layer. A thickness for the conductive film layer can then be determined by referring to, for example, a table or map, correlating the adjusted resistivity measurement with a thickness measurement for the conductive film layer. In some embodiments in accordance with the present principles, such a determination can be made by, for example, the processing device 150.

In some embodiments in accordance with the present principles, to enable a correlation between a resistivity measurement of a conductive film layer acquired by the conductive layer measurement system 110 during a temperature change of a certain range and a thickness of the conductive film layer, a calibration process can be performed. For example, in one embodiment in accordance with the present principles, a resistivity measurement of a particular conductive film layer type having a known thickness is acquired by the conductive layer measurement system 110 during a temperature change of a certain range for a plurality of conductive film types having a plurality of known thicknesses and for a plurality of temperature change ranges. A map/table can then be generated correlating resistivity measurements acquired by the conductive layer measurement system 110 for a particular conductive film layer having a known thickness for a specific temperature change range with a thickness of the particular conductive film layer.

Subsequently, when a temperature change range for a specific conductive film layer is noted by, for example, the temperature sensor 155 of FIG. 1 during a resistivity measurement, the map/table can be referred to determine a thickness of the measured conductive film layer by looking up in the table a thickness associated with the resulting resistivity measurement for the particular conductive film layer type that was measured for the particular temperature change range.

As described above, embodiments of a conductive layer measurement system 110 in accordance with the present principles can include a temperature sensor 155 for measuring temperatures and temperature variations. In some embodiments in accordance with the present principles, and as depicted in FIG. 1, the temperature sensor 155 is facing a back side/under side of the wafer 115, opposite the side on which the conductive film layer is deposited, and as such deposited films can make it difficult for a sensor to obtain an accurate temperature reading due to, for example, reflectivity. To compensate for such difficulties in reading temperature, in some embodiments in accordance with the present principles and as depicted in the embodiment of FIG. 1, in some embodiments the temperature sensor 155 can be mounted at an angle, for example a 45 degree angle, to acquire a temperature reading from the backside of the wafer 115. In some other embodiments, to compensate for difficulties in reading temperature as describe above, a temperature sensor can include an optical temperature sensor and a mirror can be used to enable a temperature sensing of the backside of the wafer 115.

Using the processes described herein in accordance with the present principles, resistivity measurements can be correlated to thickness measurement for deposited conductive film layers in a reproducible and accurate way. As such, the reproducibility and accuracy of a deposition system, and in some embodiments, a chemical vapor deposition system, can be measured and maintained.

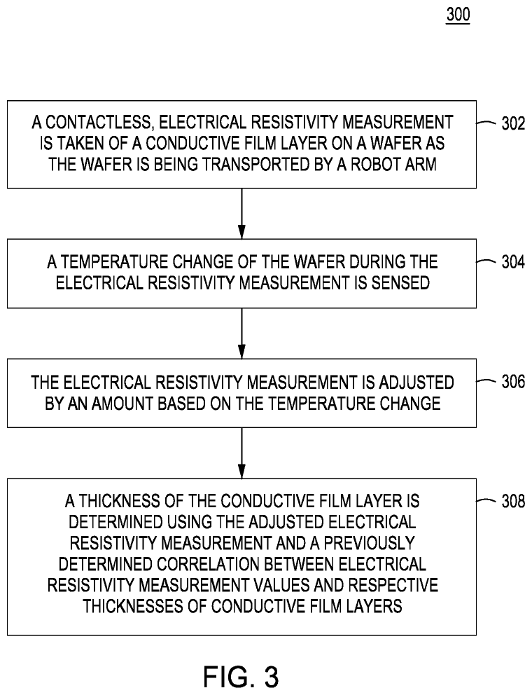

FIG. 3 depicts a flow diagram of a method for determining a thickness of a layer deposited on a wafer in accordance with an embodiment of the present principles. The method 300 begins at 302 during which a contactless, electrical resistivity measurement is taken of a conductive film layer on a wafer as the wafer is being transported by a robot arm. The method 300 can proceed to 304.

At 304, a temperature change of the wafer during the electrical resistivity measurement is sensed. The method 300 can proceed to 306.

At 306, the electrical resistivity measurement is adjusted by an amount based on the temperature change. The method 300 can proceed to 308.

At 308, a thickness of the conductive film layer is determined using the adjusted electrical resistivity measurement and a previously determined correlation between electrical resistivity measurement values and respective thicknesses of conductive film layers. The method 300 can then be exited.

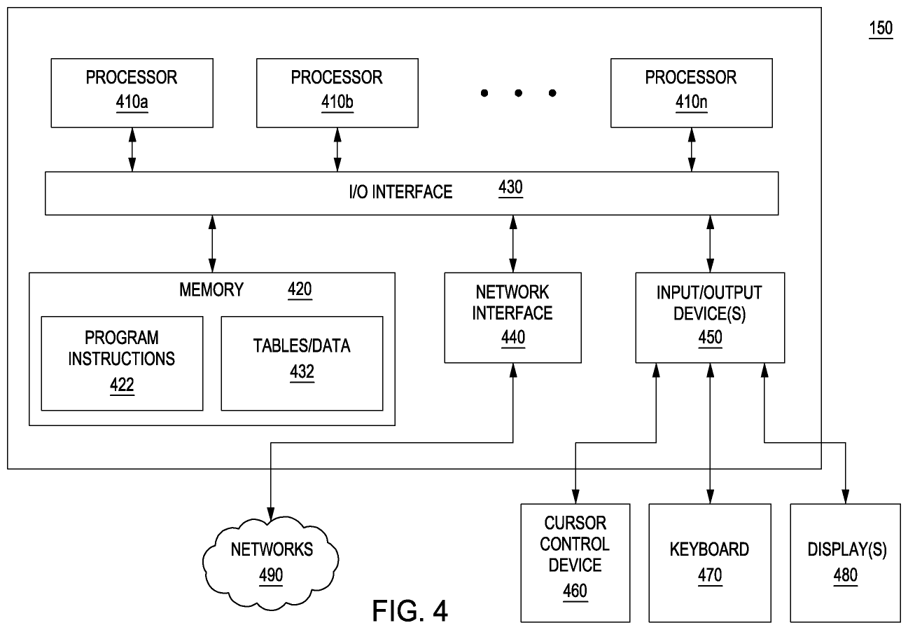

FIG. 4 depicts a high level block diagram of a processing device 150 suitable for use in the CVD process system of FIG. 1 in accordance with an embodiment of the present principles. The processing device 150 can be used to implement any other system, device, element, functionality or method of the above-described embodiments. In the illustrated embodiments, the processing device 150 can be configured to implement methods 300 and/or 500 as processor-executable executable program instructions 422 (e.g., program instructions executable by processor(s) 410).

In the illustrated embodiment, the processing device 150 includes one or more processors 410a-410n coupled to a system memory 420 via an input/output (I/O) interface 430. The processing device 150 further includes a network interface 440 coupled to I/O interface 430, and one or more input/output devices 460, such as a cursor control device keyboard 470, and display(s) 480. In some embodiments, the cursor control device keyboard 470 can be a touchscreen input device.

In different embodiments, the processing device 150 can be any of various types of devices, including, but not limited to, personal computer systems, mainframe computer systems, handheld computers, workstations, network computers, application servers, storage devices, a peripheral devices such as a switch, modem, router, or in general any type of computing or electronic device.

In various embodiments, the processing device 150 can be a uniprocessor system including one processor 410, or a multiprocessor system including several processors 410 (e.g., two, four, eight, or another suitable number). Processors 410 can be any suitable processor capable of executing instructions. For example, in various embodiments processors 410 can be general-purpose or embedded processors implementing any of a variety of instruction set architectures (ISAs). In multiprocessor systems, each of processors 410 can commonly, but not necessarily, implement the same ISA.

System memory 420 can be configured to store results of calibration processes described above, program instructions 422 and/or tables/data 432 accessible by processor 410. In various embodiments, system memory 420 can be implemented using any suitable memory technology, such as static random access memory (SRAM), synchronous dynamic RAM (SDRAM), nonvolatile/Flash-type memory, or any other type of memory. In the illustrated embodiment, program instructions and data implementing any of the elements of the embodiments described above can be stored within system memory 420. In other embodiments, program instructions and/or data can be received, sent or stored upon different types of computer-accessible media or on similar media separate from system memory 420 or the processing device 150.

In one embodiment, I/O interface 430 can be configured to coordinate I/O traffic between processor 410, system memory 420, and any peripheral devices in the device, including network interface 440 or other peripheral interfaces, such as input/output devices 450. In some embodiments, I/O interface 430 can perform any necessary protocol, timing or other data transformations to convert data signals from one component (e.g., system memory 420) into a format suitable for use by another component (e.g., processor 410). In some embodiments, the function of I/O interface 430 can be split into two or more separate components, such as a north bridge and a south bridge, for example. Also, in some embodiments some or all of the functionality of I/O interface 430, such as an interface to system memory 420, can be incorporated directly into processor 410.

Network interface 440 can be configured to allow data to be exchanged between the processing device 150 and other devices attached to the processing device 150 or a network (e.g., network 490), such as one or more external systems. In various embodiments, network 490 can include one or more networks including but not limited to Local Area Networks (LANs) (e.g., an Ethernet or corporate network), Wide Area Networks (WANs) (e.g., the Internet), wireless data networks, cellular networks, Wi-Fi, some other electronic data network, or some combination thereof. In various embodiments, network interface 440 can support communication via wired or wireless general data networks, such as any suitable type of Ethernet network, for example; via telecommunications/telephony networks such as analog voice networks or digital fiber communications networks; via storage area networks such as Fibre Channel SANs, or via any other suitable type of network and/or protocol.

Input/output devices 450 can, in some embodiments, include one or more display devices, keyboards, keypads, cameras, touchpads, touchscreens, scanning devices, voice or optical recognition devices, or any other devices suitable for entering or accessing data. Multiple input/output devices 450 can be present in the processing device 150. In some embodiments, similar input/output devices can be separate from the processing device 150.

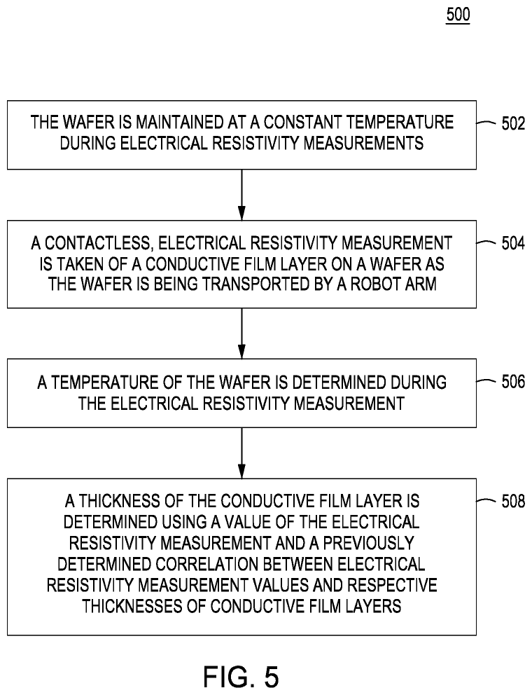

In some embodiments, the illustrated computer system can implement any of the methods described above, such as the methods illustrated by the flowchart of FIG. 3 and/or FIG. 5. In other embodiments, different elements and data can be included.

The processing device 150 of FIG. 4 is merely illustrative and is not intended to limit the scope of embodiments. In particular, the computer system and devices can include any combination of hardware or software that can perform the indicated functions of various embodiments, including computers, network devices, Internet appliances, smartphones, tablets, PDAs, wireless phones, pagers, and the like. The processing device 150 can also be connected to other devices that are not illustrated, or instead may operate as a stand-alone system. In addition, the functionality provided by the illustrated components may in some embodiments be combined in fewer components or distributed in additional components. Similarly, in some embodiments, the functionality of some of the illustrated components may not be provided and/or other additional functionality may be available.

FIG. 5 depicts a flow diagram of a method 500 for measuring a thickness of a layer deposited on a wafer in accordance with an alternate embodiment of the present principles. The method 500 of FIG. 5 begins at 502 during which the wafer is maintained at a constant temperature during an electrical resistivity measurement. As described above, in one embodiment the wafer is maintained at a constant temperature by the temperature controller 165 during an electrical resistivity measurement by the conductive layer measurement system 110. The method 500 can proceed to 504.

At 504, a contactless, electrical resistivity measurement is taken of a conductive film layer on a wafer as the wafer is being transported by a robot arm. The method 500 can proceed to 506.

At 506, a temperature of the wafer is determined during the electrical resistivity measurement. As described above, in one embodiment a temperature of the wafer is determined by the temperature sensor 155 to ensure that the wafer is being maintained at a constant temperature and to verify the temperature at which the wafer is being maintained. The method 500 can proceed to 508.

At step 508, a thickness of the conductive film layer is determined using a value of the electrical resistivity measurement and a previously determined correlation between electrical resistivity measurement values and respective thicknesses of conductive film layers. The method 500 can then be exited.

In some embodiments, a method for determining a thickness of a conductive film layer deposited on a wafer includes taking a contactless, electrical resistivity measurement of the conductive film layer on the wafer as the wafer is being transported by a robot arm, determining a temperature change of the wafer during the electrical resistivity measurement, adjusting a value of the electrical resistivity measurement by an amount based on the determined temperature change, and determining a thickness of the conductive film layer using the adjusted value of the electrical resistivity measurement and a previously determined correlation between electrical resistivity measurement values and respective thicknesses of conductive film layers.

In some embodiments, an amount to adjust a value of the electrical resistivity measurement is determined using a first calibration process, which includes taking a contactless, electrical resistivity measurement of the conductive film layer during a plurality of temperature change ranges, and comparing a value of the electrical resistivity measurement for each of the plurality of temperature change ranges with a previously determined value of an electrical resistivity measurement of the conductive film layer taken during a constant, reference temperature to determine an effect of each of the temperature change ranges on an electrical resistivity measurement. In some embodiments, the amount by which to adjust the value of the electrical resistivity measurement is proportional to the effect the temperature change has on an electrical resistivity measurement.

In some embodiments, the correlation between electrical resistivity measurement values and respective thicknesses of conductive film layers is determined using a second calibration process, which includes taking contactless, electrical resistivity measurements of a plurality of conductive film layers, taking thickness measurements of the plurality of conductive film layers using a thin-film metrology, and correlating the contactless, electrical resistivity measurements of the plurality of conductive film layers with respective thin-film, metrology thickness measurements of the plurality of conductive film layers.

In some embodiments, the second calibration process includes taking contactless, electrical resistivity measurements of a plurality of conductive film layers having known thicknesses, and correlating the contactless, electrical resistivity measurements of the plurality of conductive film layers with respective thicknesses of the plurality of conductive film layers.

In some embodiments, a method for determining a thickness of a conductive film layer deposited on a wafer includes maintaining the wafer at a constant temperature during an electrical resistivity measurement, taking a contactless, electrical resistivity measurement of the conductive film layer on the wafer as the wafer is being transported by a robot arm, determining a temperature of the wafer during the electrical resistivity measurement, and determining a thickness of the conductive film layer using a value of the electrical resistivity measurement and a previously determined correlation between electrical resistivity measurement values and respective thicknesses of conductive film layers.

In some embodiments, the correlation between electrical resistivity measurement values and respective thicknesses of conductive film layers is determined using a calibration process, which includes taking contactless, electrical resistivity measurements of a plurality of conductive film layers, taking thickness measurements of the plurality of conductive film layers using a thin-film metrology, and correlating the contactless, electrical resistivity measurements of the plurality of conductive film layers with respective thin-film, metrology thickness measurements of the plurality of conductive film layers. In alternate embodiments, the calibration process includes taking contactless, electrical resistivity measurements of a plurality of conductive film layers having known thicknesses, and correlating the contactless, electrical resistivity measurements of the plurality of conductive film layers with respective thicknesses of the plurality of conductive film layers.

In some embodiments, a system for determining a thickness of a conductive film layer deposited on a wafer includes at least two eddy current sensors to capture, electrical resistivity measurements of the conductive film layer, wherein a first of the at least two eddy current sensors is configured to capture electrical resistivity measurements from above the wafer and wherein a second of the at least two eddy current sensors is configured to capture electrical resistivity measurements from below the wafer, a temperature sensor to sense at least a temperature of the wafer, and a processing device including a memory for storing program instructions, tables and data, and a processor for executing the program instructions. When executed by the processor, the program instructions cause the system to capture a contactless, electrical resistivity measurement of the conductive film layer on the wafer as the wafer is being transported by a robot arm across the at least two eddy current sensors, determine a temperature change of the wafer during the electrical resistivity measurement using the temperature sensor, adjust a value of the electrical resistivity measurement by an amount based on the determined temperature change and determine a thickness of the conductive film layer using the adjusted value of the electrical resistivity measurement and a previously determined correlation between electrical resistivity measurement values and respective thicknesses of conductive film layers. In some embodiments, the previously determined correlation between electrical resistivity measurement values and respective thicknesses of conductive film layers is stored as a table in the memory of the processing device.

In some embodiments, a system for determining a thickness of a conductive film layer deposited on a wafer includes at least two eddy current sensors to take electrical resistivity measurements of the conductive film layer, wherein a first of the at least two eddy current sensors is configured to capture electrical resistivity measurements from above the wafer and wherein a second of the at least two eddy current sensors is configured to capture electrical resistivity measurements from below the wafer, a temperature controller to control at least a temperature of the wafer, a temperature sensor to sense at least a temperature of the wafer, and a processing device including a memory for storing program instructions, tables and data, and a processor for executing the program instructions. When executed by the processor, the program instructions cause the system to maintain the wafer at a constant temperature during an electrical resistivity measurement using the temperature controller, capture a contactless, electrical resistivity measurement of the conductive film layer on the wafer as the wafer is being transported by a robot arm across the at least two eddy current sensors, determine a temperature of the wafer during the electrical resistivity measurement using the temperature sensor, and determine a thickness of the conductive film layer using a value of the electrical resistivity measurement and a previously determined correlation between electrical resistivity measurement values and respective thicknesses of conductive film layers.

While various items are illustrated as being stored in memory or on storage while being used, these items or portions of these items may be transferred between memory and other storage devices for purposes of memory management and data integrity. In some embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from the processing device 150 can be transmitted to the processing device 150 via transmission media or signals such as electrical, electromagnetic, or digital signals, conveyed via a communication medium such as a network and/or a wireless link.

Various embodiments can further include receiving, sending or storing instructions and/or data implemented in accordance with the foregoing description upon a computer-accessible medium or via a communication medium. In general, a computer-accessible medium may include a storage medium or memory medium such as magnetic or optical media, e.g., disk or DVD/CD-ROM, volatile or non-volatile media such as RAM (e.g., SDRAM, DDR, RDRAM, SRAM, and the like), ROM, and the like.

The methods described herein can be implemented in software, hardware, or a combination thereof, in different embodiments. In addition, the order of methods can be changed, and various elements may be added, reordered, combined, omitted or otherwise modified. All examples described herein are presented in a non-limiting manner. Various modifications and changes can be made having benefit of the present disclosure. Realizations in accordance with embodiments have been described in the context of particular embodiments. These embodiments are meant to be illustrative and not limiting. Many variations, modifications, additions, and improvements are possible. Accordingly, plural instances can be provided for components described herein as a single instance. Boundaries between various components, operations and data stores are somewhat arbitrary, and particular operations are illustrated in the context of specific illustrative configurations. Other allocations of functionality are envisioned and can fall within the scope of claims that follow. Finally, structures and functionality presented as discrete components in the example configurations can be implemented as a combined structure or component.

While the foregoing is directed to embodiments of the present disclosure, other and further embodiments of the disclosure may be devised without departing from the basic scope thereof.

1. A method for determining a thickness of a conductive film layer deposited on a wafer, comprising:
taking a contactless, electrical resistivity measurement of the conductive film layer on the wafer as the wafer is being transported by a robot arm;
determining a temperature change of the wafer during the electrical resistivity measurement;
adjusting a value of the electrical resistivity measurement by an amount based on the determined temperature change; and
determining a thickness of the conductive film layer using the adjusted value of the electrical resistivity measurement and a previously determined correlation between electrical resistivity measurement values and respective thicknesses of conductive film layers.

2. The method of claim 1, wherein the contactless, electrical resistivity measurement is performed by at least two eddy current sensors.

3. The method of claim 2, wherein the temperature change is determined as the wafer is moved across the at least two eddy sensors.

4. The method of claim 1, wherein an amount to adjust a value of the electrical resistivity measurement is determined using a first calibration process.

5. The method of claim 4, wherein the first calibration process comprises:
taking a contactless, electrical resistivity measurement of the conductive film layer during a plurality of temperature change ranges; and
comparing a value of the electrical resistivity measurement for each of the plurality of temperature change ranges with a previously determined value of an electrical resistivity measurement of the conductive film layer taken during a constant, reference temperature to determine an effect of each of the temperature change ranges on an electrical resistivity measurement.

6. The method of claim 5, wherein the amount by which to adjust the value of the electrical resistivity measurement is proportional to the effect the temperature change has on an electrical resistivity measurement.

7. The method of claim 1, wherein the correlation between electrical resistivity measurement values and respective thicknesses of conductive film layers is determined using a second calibration process.

8. The method of claim 7, wherein the second calibration process comprises:
taking contactless, electrical resistivity measurements of a plurality of conductive film layers;
taking thickness measurements of the plurality of conductive film layers using a thin-film metrology; and
correlating the contactless, electrical resistivity measurements of the plurality of conductive film layers with respective thin-film, metrology thickness measurements of the plurality of conductive film layers.

9. The method of claim 8, wherein the correlation is stored in a table.

10. The method of claim 7, wherein the second calibration process comprises:
taking contactless, electrical resistivity measurements of a plurality of conductive film layers having known thicknesses; and
correlating the contactless, electrical resistivity measurements of the plurality of conductive film layers with respective thicknesses of the plurality of conductive film layers.

11. A system for determining a thickness of a conductive film layer deposited on a wafer, comprising:
at least two eddy current sensors to capture, electrical resistivity measurements of the conductive film layer, wherein a first of the at least two eddy current sensors is configured to capture electrical resistivity measurements from a first side of the wafer and wherein a second of the at least two eddy current sensors is configured to capture electrical resistivity measurements from a second side of the wafer;
a temperature sensor to sense at least a temperature of the wafer; and
a processing device including a memory for storing program instructions, tables and data, and a processor for executing the program instructions to cause the system to:
using the at least two eddy current sensors, capture a contactless, electrical resistivity measurement of the conductive film layer on the wafer as the wafer is being transported by a robot arm across the at least two eddy current sensors;
using the temperature sensor, determine a temperature change of the wafer during the electrical resistivity measurement;
adjust a value of the electrical resistivity measurement by an amount based on the determined temperature change; and
determine a thickness of the conductive film layer using the adjusted value of the electrical resistivity measurement and a previously determined correlation between electrical resistivity measurement values and respective thicknesses of conductive film layers.

12. The system of claim 11, wherein the processing device determines an amount to adjust a value of the electrical resistivity measurement based on a first calibration process.

13. The system of claim 12, wherein the first calibration process comprises:
taking a contactless, electrical resistivity measurement of the conductive film layer during a plurality of temperature change ranges; and
comparing a value of the electrical resistivity measurement for each of the plurality of temperature change ranges with a previously determined value of an electrical resistivity measurement of the conductive film layer taken during a constant, reference temperature to determine an effect of each of the temperature change ranges on an electrical resistivity measurement.

14. The system of claim 13, wherein the amount by which to adjust the value of the electrical resistivity measurement is proportional to the effect the temperature change has on an electrical resistivity measurement.

15. The method of claim 1, comprising:
maintaining the wafer at a constant temperature during the electrical resistivity measurement;
determining a temperature of the wafer during the electrical resistivity measurement; and
determining a thickness of the conductive film layer using a value of the electrical resistivity measurement and a previously determined correlation between electrical resistivity measurement values and respective thicknesses of conductive film layers at the determined temperature.

16. The method of claim 15, wherein the correlation between electrical resistivity measurement values and respective thicknesses of conductive film layers is determined using a calibration process.

17. (canceled)

18. The method of claim 15, wherein the correlation is stored in a table.

19. The method of claim 16, wherein the calibration process comprises:
taking contactless, electrical resistivity measurements of a plurality of conductive film layers having known thicknesses; and
correlating the contactless, electrical resistivity measurements of the plurality of conductive film layers with respective thicknesses of the plurality of conductive film layers.

20. A system for determining a thickness of a conductive film layer deposited on a wafer, comprising:
at least two eddy current sensors to take electrical resistivity measurements of the conductive film layer, wherein a first of the at least two eddy current sensors is configured to capture electrical resistivity measurements from above the wafer and wherein a second of the at least two eddy current sensors is configured to capture electrical resistivity measurements from below the wafer;
a temperature controller to control at least a temperature of the wafer;
a temperature sensor to sense at least a temperature of the wafer; and
a processing device including a memory for storing program instructions, tables and data, and a processor for executing the program instructions to cause the system to:
using the temperature controller, maintain the wafer at a constant temperature during an electrical resistivity measurement;
using the at least two eddy current sensors, capture a contactless, electrical resistivity measurement of the conductive film layer on the wafer as the wafer is being transported by a robot arm across the at least two eddy current sensors;
using the temperature sensor, determine a temperature of the wafer during the electrical resistivity measurement; and
determine a thickness of the conductive film layer using a value of the electrical resistivity measurement and a previously determined correlation between electrical resistivity measurement values and respective thicknesses of conductive film layers at the determined temperature.

21. The system of claim 20, wherein the correlation between electrical resistivity measurement values and respective thicknesses of conductive film layers is determined using a calibration process comprising:
taking contactless, electrical resistivity measurements of a plurality of conductive film layers having known thicknesses at a plurality of temperatures; and
correlating the contactless, electrical resistivity measurements of the plurality of conductive film layers with respective thicknesses of the plurality of conductive film layers for each of the plurality of temperatures.
